(19) United States
(12) Patent Application Publication
(10) Pub. No.: US 2021/0114939 A1
(43) Pub. Date: Apr. 22, 2021

(54) METHOD OF PRODUCING AN OPTICALLY TRANSPARENT FILM

(71) Applicant: Power Roll Limited, Sunderland (GB)

(72) Inventor: Alexander John Topping, Sunderland (GB)

(21) Appl. No.: 16/500,365

(22) PCT Filed: Apr. 3, 2018
(86) PCT No.: PCT/GB2018/050902

§ 371 Date: Oct. 2, 2019

(30) Foreign Application Priority Data
Apr. 4, 2017 (GB) 1705444.6

(51) Int. Cl. C04B 35/46; C04B 35/64; C04B 35/622; G02F 1/03

(52) U.S. Cl. CPC C04B 35/46; C04B 35/64; C04B 35/62222; G02F 1/0305; C04B 2235/3232; C04B 2235/3262; C04B 2235/945; C04B 2235/428; C04B 2235/528; C04B 2235/6025; C04B 2235/667; C04B 2235/9653; C04B 2235/3284

(57) ABSTRACT

The invention relates to a method of producing an optically transparent film, the method comprising the steps of: providing a ceramic material, wherein the ceramic material is transparent to light having a wavelength of from 380 nm to 1000 nm; and using electromagnetic radiation to adhere together at least some of the components of the ceramic material, wherein the electromagnetic radiation has a wavelength shorter than 450 nm.

The present invention relates to a method of producing an optically transparent film.

Processing coated polymer substrates can be difficult. The manufacture of coated polymer substrates often requires heat but the thermal loads delivered often overheat the substrate causing deformation and structural failures of the substrate and other modes of substrate damage.

Current manufacturing techniques often include pre-treating the substrate to improve the adhesion of other components. This reduces the heating required but the resultant processes are complex.

The present invention aims to reduce the complexity of processes for producing optically transparent films.

In accordance with a first aspect of the present invention there is provided a method of producing an optically transparent film, the method comprising the steps of:
providing a ceramic material, wherein the ceramic material is transparent to light having a wavelength of from 380 nm to 1000 nm; and
using electromagnetic radiation to adhere together at least some of the components of the ceramic material, wherein the electromagnetic radiation has a wavelength shorter than 450 nm.

The electromagnetic radiation typically has a distribution of wavelengths shorter than 450 nm.

The optically transparent film may be a barrier. The barrier may be impermeable or at least substantially impermeable to one or more of fluid, gas, oxygen, moisture, water vapour and odours.

The ceramic material typically comprises at least two components. The at least two components are typically one or more of a different size, a different shape and have a different chemical composition.

When the at least two components are a different size, the size of a first component is normally 25 to 35%, typically 30% smaller than a second component. When there are three components, a third component is normally 25 to 35%, typically 30% smaller than the first component.

The at least two components are, and when there are three components the third component is, typically at least substantially and/or nominally spherical, normally spherical. When the at least two components are at least substantially and/or nominally spherical and a different size, the diameter of a first component is normally 25 to 35%, typically 30% smaller than a second component. When there are three components that are at least substantially and/or nominally spherical, the diameter of a third component is normally 25 to 35%, typically 30% smaller than the first component.

When the components of the ceramic material are a different size and/or different shape, high or higher packing density is achieved by the development of a unit cell based upon the arrangement by percentage volume that each component would take up if packed together with other components to the highest possible density into a unit cuboid. This gives the respective percentage volumes of the many components that should be combined.

It may be an advantage of the present invention that one or more of the size, shape and chemical composition of the at least two components of the ceramic material can be used to increase the packing density of the components of the ceramic material. When the packing density is increased, the mechanical strength and/or impermeability of the optically transparent film is typically increased.

The at least some of the components of the ceramic material may be oblate in shape and/or have a high aspect ratio. The packing density of the components of the ceramic material may be increased when the at least some of the components of the ceramic material are oblate in shape and/or have a high aspect ratio.

There may be only a trace amount of the at least some of the components in the ceramic material. There may be more of the at least some of the components in the ceramic material, the ceramic material may comprise from 1 to 74%, typically from 20 to 60% of the ceramic material. The amount of the at least some of the components in the ceramic material may be referred to as the loading of the at least some of the components. The loading of the at least some of the components may be used to control the properties of the optically transparent film.

The ceramic material typically absorbs the electromagnetic radiation having a wavelength of shorter than 450 nm. The at least some components of the ceramic material typically comprise an absorbing material. The absorbing material normally absorbs at least some of the electromagnetic radiation. The absorbing material normally does not substantially absorb light having a wavelength of from 380 nm to 1000 nm.

The electromagnetic radiation used to adhere together at least some of the components of the ceramic material may be pulsed electromagnetic radiation. The electromagnetic radiation may be generated by a flashlamp. The electromagnetic radiation used to adhere together at least some of the components of the ceramic material normally has a wavelength shorter than 450 nm, typically shorter than 380, and optionally from 200 nm to 450 nm.

The ceramic material may be transparent to light having a wavelength of from 380 nm to 760 nm.

The pulsed electromagnetic radiation may be generated by a pulsed light discharge system. One or more of an appropriate choice of plasma driving conditions, design of an optical transfer system and optical filtering to remove substantially non-useful optical irradiation may be used to optimise the pulsed light discharge system.

The voltage of the pulsed electromagnetic radiation and/or the time the pulsed electromagnetic radiation is on should typically be adjusted, normally minimised, to maintain an operating window for successful adhesion of the at least some of the components of the ceramic material without deleterious damage to the substrate.

The step of using electromagnetic radiation to adhere together at least some of the components of the ceramic material may be pulsed photonic curing. Without wishing to be bound by theory, following curing, the at least some of the components of the ceramic material are adhered together with a greater cohesive strength than the pre-cured film.

The ceramic material is typically dense. The at least some of the components of the ceramic material may be spherical. When the at least some of the components of the ceramic material are spherical and substantially the same type and/or chemical composition, the density of the ceramic material is normally from 0.5 to 0.75, typically from 0.523 to 0.740. When the at least some of the components of the ceramic material are spherical and comprise components of a first and a second type and/or chemical composition, the density of the ceramic material is normally greater than 0.75 and typically close to 1. The ceramic material is typically non-porous.

The method may further comprise providing a substrate. The method may include the step of depositing and/or coating the ceramic material on the substrate.

The substrate is typically electrically non-conductive. The step of depositing and/or coating the ceramic material on the substrate is typically done in ambient atmosphere and/or at atmospheric pressure.

The step of adhering together at least some of the components of the ceramic material typically includes one or more of fusing, sticking, curing and sintering at least some of the components together. The step of adhering together at least some of the components of the ceramic material typically includes one or more of fusing, sticking, curing and sintering at least some of the components together and to the substrate and/or another solid present.

The ceramic material is transparent to light having a wavelength of from 380 nm to 1000 nm. This typically means that light having a wavelength of from 380 nm to 1000 nm will pass through the ceramic material without, or at least substantially without, being absorbed and/or scattered. This may mean that light having a wavelength of from 380 nm to 1000 nm is not absorbed or at least not substantially absorbed by the ceramic material.

The method of the present invention is a method of producing an optically transparent film. An optically transparent film typically transmits most and reflects and/or absorbs little of the visible light that it is incident upon it.

An optically transparent film is generally considered to have transparency over the human visible spectrum and/or between 360 nm and 760 nm. The optically transparent film may be considered optically transparent if it can pass a fraction of the visible spectrum but still allow for human viewing of objects through it. The ceramic material may and/or may therefore be considered substantially transparent to light having a wavelength of from 380 nm to 1000 nm.

Useful transparency is herein considered to be transparency across or within the visible spectrum that allows for sufficient visible light to pass through the optically transparent film for the desired function to be achieved. Normally the whole of the visible spectrum transmission is maximised but in some cases reduced transmission is acceptable so long as the functional element of the optically transparent film is maintained.

The functional element of the optically transparent film is typically one or more of a gas barrier, permeation barrier, selective gas permeation barrier, anti fungal, self cleaning, electrically conductive, UV blocking, packaging for oxygen and/or moisture sensitive foodstuffs, packaging for oxygen and/or moisture sensitive articles, packaging for use in ethical applications, encapsulation of gas and/or moisture sensitive articles and/or components, encapsulation of electrically conductive and/or electrostatically dissipative articles and/or components, protection of ultra-violet (UV) sensitive articles, part of a photochromic and/or thermochromic system, and a transparent electrically conducting film.

The ceramic material is typically inorganic. At least one of the components of the ceramic material may be metal. At least one of the components of the ceramic material may be a non-metal. The ceramic material may be non-metallic. The ceramic material is normally particulate. The ceramic material may be an oxide and/or a nitride and/or a sulphide and/or a fluoride and/or a bromide. The ceramic material may comprise one or more of aluminium, silicon, titanium, manganese, zinc, vanadium, lithium, magnesium, niobium, lanthanum, cerium, lead, tin, indium, yttrium, ytterbium, silver tungsten, molybdenum and tantalum. The ceramic material may comprise one or more of aluminium oxide, silicon oxide, titanium oxide, manganese oxide, zinc oxide, vanadium oxide, tungsten oxide, molybdenum oxide, titanium nitride, lithium niobate and silver bromide.

The optically transparent film is typically resin-free.

The optically transparent film may typically consist essentially of inorganic material.

The ceramic material may comprise nanoparticles. The least some of the components of the ceramic material may be and/or may comprise nanoparticles. The method may include the step of adding nanoparticles of the ceramic material to a fluid, typically a liquid to produce a nanoparticle suspension.

The method normally includes the step of calculating the energy of the electromagnetic radiation needed to adhere together at least some of the components of the ceramic material. The energy of the electromagnetic radiation is typically related to the absorption characteristics of the ceramic material. The wavelength of the electromagnetic radiation used to adhere together at least some of the components of the ceramic material is typically selected depending on the energy of the electromagnetic radiation needed and/or the optical absorption of the ceramic material.

The optically transparent film may be part of an optoelectronic device. The optoelectronic device may comprise a series of grooves wherein each groove of the series of grooves has a first and a second face and a cavity therebetween. The cavity is typically at least partially filled with a first semiconductor material, the first face coated with a conductor material and the second face coated with a second semiconductor material. The cavity may be referred to as a trough.

In use, the optoelectronic device is exposed to light. The light typically comprises one or more of ultraviolet, infrared and visible light. Electrical energy and/or electricity, normally direct electrical current, is typically generated when the semiconductor and another semiconductor materials are, and normally a junction between the semiconductor and another semiconductors is, exposed to the light.

The optically transparent film may be a barrier to ultra-violet (UV) light. The optically transparent film may be a barrier to ultra-violet light if it absorbs in the UV. Ultra-violet light or at least some ultra-violet light and/or ultra-violet light of one or more wavelengths is typically not able to pass through the optically transparent film.

The optically transparent film may be one or more of part of a packaging for oxygen and/or moisture sensitive foodstuffs, packaging for oxygen and/or moisture sensitive articles, packaging for use in ethical applications, encapsulation of gas and/or moisture sensitive articles and/or components, encapsulation of electrically conductive and/or electrostatically dissipative articles and/or components, protection of ultra-violet (UV) sensitive articles, part of a photochromic and/or thermochromic system, and a transparent electrically conducting film.

The step of using electromagnetic radiation to adhere together at least some of the components of the ceramic material and/or adhere the at least some of the components to another solid present may be a photonic process.

It may be an advantage of the present invention that the at least some of the components of the ceramic material absorb sufficient electromagnetic radiation having a wavelength shorter than 450 nm so that the at least some of the components of the ceramic material adhere together to generate the optically transparent film. The at least some of the components of the ceramic material typically do not absorb too much of the electromagnetic radiation such that the ceramic material is damaged and/or too many defects in the material are created to inhibit the production of and/or proper function of the optically transparent film.

The electromagnetic radiation used to adhere together at least some of the components of the ceramic material normally has sufficient energy to momentarily increase the thermal energy and/or the temperature of the least some of the components of the ceramic material. It is normally this increased thermal energy and/or temperature that results in the at least some of the components adhering together. The electromagnetic radiation used to adhere together at least some of the components of the ceramic material normally heats the least some of the components of the ceramic material.

When the at least some of the components of the ceramic material are adjacent to the substrate, the electromagnetic radiation normally adheres the at least some of the components to the substrate.

The optically transparent film may be from 50 to 1000 nm thick, typically from 100 to 400 nm thick.

The step of using electromagnetic radiation to adhere together at least some of the components of the ceramic material, wherein the electromagnetic radiation has a wavelength shorter than 450 nm, typically includes matching or at least substantially matching an absorption spectrum of the at least some of the components with an emission spectrum of the electromagnetic radiation used. Such wavelengths are emitted by several types of light source including, but not limited to, hot filaments, LED's and flash lamps.

The inventors of the present invention note that some materials are known to have a different optical absorption spectrum and/or behaviour when in nanoparticle form. The inventors of the present invention have appreciated that this can mean optically transparent films can be made with a wider range of materials, compared to those that would normally be available if only bulk optical properties were considered.

One or more of the wavelength, frequency and energy of electromagnetic radiation used to adhere together at least some of the components of the ceramic material, is typically adjusted to affect one or more of the adhesion, cohesion and homogeneity of at least some of the components of the ceramic material. It may be an advantage of the present invention that this can be used to improve the optical performance of the optically transparent film.

The method of producing an optically transparent film may include the step of producing an optically transparent film comprising more than one layer. The steps of providing a ceramic material, wherein the ceramic material is transparent to light having a wavelength of from 380 nm to 1000 nm; and using electromagnetic radiation to adhere together at least some of the components of the ceramic material, wherein the electromagnetic radiation has a wavelength shorter than 450 nm, may be repeated for each layer of the film.

The ceramic material may be substantially transparent to light having a wavelength of from 380 nm to 1000 nm.

Embodiments of the invention will now be described by way of a number of examples.

### EXAMPLE 1

A nanoparticle ceramic material in the form of a paste comprising a mono-dispersion of manganese doped titanium dioxide nanoparticles in ethanol was ultrasonically agitated to obtain good dispersion. This was then applied with a Mayer rod to give a nominal 10-20 microns of coating onto a PET surface (also referred to as a substrate). Little or no reticulation was observed while the solution rapidly dried. The Mayer rod has a grooved surface so that a known volume of liquid coating material is left behind when the rod is drawn across a flat surface. The surface was treated with single pulses of electromagnetic radiation having a 200-1000 nm wavelength and lasting from 100 to 1000 microseconds, to adhere together some of the components of the nanoparticle ceramic paste material. The resultant film showed excellent adhesion and improved the gas barrier properties of the film for oxygen transmission rate (OTR). The control sample had an OTR of 38.8 cc/m²/day and the coated sample had an OTR of 5.6 cc/m²/day. The nanoparticle ceramic paste material was transparent to light having a wavelength of 360-760 nm.

### EXAMPLE 2

Two samples were prepared, the first using a single component ceramic material of titanium dioxide stabilised in water and the second ceramic material using that same solution with the addition of 3% of ZnO and diluted with ethanol. The two resultant films would have different thicknesses due to the reduced solids content of the second film. However the second sample used different sizes of particles, the ratio of these particles being 3:1. The packing density of the particles was therefore improved. The resultant barrier properties of these films showed better gas barrier properties for the two component system over the thicker single component film. Barrier performance was therefore different. The first, thicker single component film had an OTR of 10.6 cc/m²/day and a moisture vapour transmission rate (MVTR) of 23.7 g/m³/day compared to the thinner two component film with an OTR of 4.66 cc/m²/day and a MVTR of 5.02 g/m³/day after similar treatment, as outlined above for example 1. This illustrates that the small addition of the second nanoparticle has had a beneficial effect, unexpectedly exceeding the properties that would be expected based on the thicker film. The otherwise 3-times thicker film due to solids weight was made to the same thickness as the two component film.

### EXAMPLE 3

Samples of ceramic material were prepared using suspensions of manganese doped titanium dioxide nanoparticles of 50 nm size; silicon nanoparticles of 5-15 nm size; hollow silicon nanoparticles of 20 nm size; manganese doped zinc oxide of 50 nm size; zinc oxide of 20 nm size and vanadium doped zinc oxide of 30 nm size. All the materials were volumetrically mixed with 5 ml of ethanol and spray coated onto a carrier PET web. All samples were exposed to electromagnetic radiation to adhere together at least some of their components, wherein the electromagnetic radiation had a wavelength of 200-1000 nm. The silicon dioxide 5-15 nm particle size samples showed no reasonable adhesion when tape tested due to their very low absorption in the 200 to 450 nm wavelength range. Initial voltage pulses of below 500 volts with pulse durations of 1000 microseconds gave samples with little or no reasonable adhesion. Of the remaining samples all showed good results when exposed to pulses of 150% of the initial voltage pulse, that is 700-750 volts for 300 microsecond duration at a wavelength of 200-1000 nm.

The inventors of the present invention have appreciated that when increasing the voltage discharge in a xenon discharge lamp by 50%, the wavelength intensity below 450 nm is increased some 5 fold over that of the lower voltage pulse. So even with a reduction in pulse width of 70% the total delivered energy below 450 nm for the higher pulse is 150% that of the lower voltage pulse.

The voltages and pulse durations used are lamp and machine specific so will vary according to the system used.

1. A method of producing an optically transparent film, the method comprising the steps of:
providing a ceramic material, wherein the ceramic material is transparent to light having a wavelength of from 380 nm to 1000 nm; and
using electromagnetic radiation to adhere together at least some of the components of the ceramic material, wherein the electromagnetic radiation has a wavelength shorter than 450 nm.

2. A method as claimed in claim 1, wherein the electromagnetic radiation has a distribution of wavelengths shorter than 450 nm.

3. A method as claimed in claim 1, wherein the ceramic material comprises at least two components, the at least two components are one or more of a different size, a different shape and have a different chemical composition.

4. A method as claimed in claim 3, wherein the at least two components are at least substantially spherical.

5. A method as claimed in claim 4, wherein the at least two components are a different size, the diameter of a first component is 25 to 35% smaller than a second component.

6. A method as claimed in claim 1, wherein the at least some of the components of the ceramic material are oblate in shape.

7. A method as claimed in claim 1, wherein there is only a trace amount of the at least some of the components in the ceramic material.

8. A method as claimed in claim 1, wherein the ceramic material absorbs the electromagnetic radiation having a wavelength of shorter than 450 nm.

9. A method as claimed in claim 1, wherein the electromagnetic radiation used to adhere together at least some of the components of the ceramic material is pulsed electromagnetic radiation.

10. A method as claimed in claim 9, wherein the pulsed electromagnetic radiation is generated by a pulsed light discharge system.

11. A method as claimed in claim 1, wherein the electromagnetic radiation used to adhere together at least some of the components of the ceramic material has a wavelength of from 200 nm to 450 nm.

12. A method as claimed in claim 1, wherein the ceramic material is transparent to light having a wavelength of from 380 nm to 760 nm.

13. A method as claimed in claim 1, wherein the method further comprises providing a substrate, the method including the step of depositing the ceramic material on the substrate.

14. A method as claimed in claim 13, wherein the substrate is electrically non-conductive, the step of depositing the ceramic material on the substrate is done in ambient atmosphere.

15. A method as claimed in claim 1, wherein the method further includes the step of calculating the energy of the electromagnetic radiation needed to adhere together the at least some of the components of the ceramic material.

16. A method as claimed in claim 13, wherein when the at least some of the components of the ceramic material are adjacent to the substrate, the electromagnetic radiation adheres the at least some of the components to the substrate.

17. A method as claimed in claim 1, wherein the optically transparent film is part of an optoelectronic device, the optoelectronic device comprising a series of grooves wherein each groove of the series of grooves has a first and a second face and a cavity therebetween, the cavity is at least partially filled with a first semiconductor material, the first face coated with a conductor material and the second face coated with a second semiconductor material.

18. A method as claimed in claim 17, wherein the optically transparent film is from 100 to 400 nm thick.

19. A method as claimed in claim 14, wherein when the at least some of the components of the ceramic material are adjacent to the substrate, the electromagnetic radiation adheres the at least some of the components to the substrate.

20. A method as claimed in claim 14, wherein when the at least some of the components of the ceramic material are adjacent to the substrate, the electromagnetic radiation adheres the at least some of the components to the substrate.
